(19) United States
(12) Patent Application Publication
(10) Pub. No.: US 2024/0334674 A1
(43) Pub. Date: Oct. 3, 2024

(54) SEMICONDUCTOR DEVICE AND METHOD OF FORMING THE SAME

(71) Applicant: Fujian Jinhua Integrated Circuit Co., Ltd., Quanzhou City (CN)

(72) Inventors: GUANGRONG WANG, Quanzhou City (CN); Feng-Lun Wu, Quanzhou City (CN); Chung-Ping Hsia, Quanzhou City (CN); MIAO SUN, Quanzhou City (CN)

(73) Assignee: Fujian Jinhua Integrated Circuit Co., Ltd., Quanzhou City (CN)

(21) Appl. No.: 18/227,326

(22) Filed: Jul. 28, 2023

(30) Foreign Application Priority Data
Mar. 29, 2023 (CN) 202310319292.4
Mar. 29, 2023 (CN) 202320651005.5

(51) Int. Cl. H10B 12/00; H01L 21/8234; H01L 27/092; H01L 29/66

(52) U.S. Cl. CPC H10B 12/053; H01L 21/823431; H01L 21/823481; H01L 27/0924; H01L 29/66795; H10B 12/34

(57) ABSTRACT

A semiconductor device and a method of forming the same are disclosed. The semiconductor device includes a substrate, a plurality of active areas, a shallow trench isolation and a plurality of buried gates. The active areas are formed on the substrate, wherein each active area includes a semiconductor layer, and a first interface exists between the semiconductor layer and the substrate. The shallow trench isolation is disposed on the substrate and surrounds the active areas. Each buried gates is buried in one of the plurality of active areas and disposed above the first interface. Accordingly, the isolation effect between the active areas can be enhanced on the condition of maintaining a certain level of integration. Meanwhile, the possible device defects derived from the raised level of integration can be ameliorated.

### BACKGROUND OF THE INVENTION

### 1. Field of the Invention

The present invention generally relates to a semiconductor device and a method of forming the same, and more particularly, to a semiconductor device including active areas and shallow trench isolation and a method of forming the same.

### 2. Description of the Prior Art

With the miniaturization of semiconductor devices and the complexity of integrated circuits, the size of components is constantly decreasing and the structure is constantly changing. Therefore, maintaining the performance of small-sized semiconductor components is the main goal of the industry at present. In a semiconductor manufacturing process, a plurality of active areas (AAs) are defined on the substrate as a base, and then required components are formed on the active areas. Generally speaking, active areas are multiple patterns formed on the substrate by photolithographic patterning and etching processes. However, under the requirement of miniaturization, the width of active areas is getting smaller, and the spacing between active areas is also gradually reduced. As a result, the manufacturing process would face a variety of restrictions and challenges, and thus it is hard to manufacture products fulfilling the requirements.

### SUMMARY OF THE INVENTION

The present invention provides a semiconductor device and a method of forming the same, which uses a mask layer to define a profile of an active area. While a cross section of the active area has a profile wider at top and narrower at bottom, a cross section of a shallow trench isolation between the active areas has a profile narrower at top and wider at bottom. In this way, the semiconductor device can maintain a certain integration level, and at the same time, the adjacent active areas can be effectively isolated by the shallow trench isolation so as to provide an improved insulation effect.

In order to achieve the above objectives, one embodiment of the present invention provides a semiconductor device, which includes a substrate, a plurality of active areas, a shallow trench isolation, and a plurality of buried gates. The active areas are disposed on the surface of the substrate. Each of the active areas comprises a semiconductor layer, which has a first interface with the substrate. The shallow trench isolation is disposed on the substrate and surrounds the active areas. Each of the buried gates is buried in one of the active areas and located above the first interface.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a schematic diagram illustrating a top view of the semiconductor device according to a first embodiment of the present invention.

FIG. 2 is a schematic diagram illustrating a cross-sectional view of the semiconductor device taken along A-A′ and B-B′ lines of FIG. 1, respectively.

FIG. 3 to FIG. 11 are schematic diagrams illustrating a forming method of a semiconductor device according to a second embodiment in the present disclosure, wherein:

FIG. 3 is a top view of a semiconductor device after a process of forming a mask layer;

FIG. 4 is a cross-sectional view of a semiconductor device taken along A-A′ and B-B′ lines of FIG. 3, respectively;

FIG. 5 is a cross-sectional view of a semiconductor device after a deposition process;

FIG. 6 is a cross-sectional view of a semiconductor device after another deposition process;

FIG. 7 is a cross-sectional view of a semiconductor device after forming a semiconductor layer;

FIG. 8 is a top view of a semiconductor device after removing the mask layer;

FIG. 9 is a cross-sectional view of a semiconductor device taken along A-A′ and B-B′ lines of FIG. 8, respectively;

FIG. 10 is a top view of a semiconductor device after a cutting process; and

FIG. 11 is a cross-sectional view of a semiconductor device taken along A-A′ and B-B′ lines of FIG. 10, respectively.

FIG. 12 is a cross-sectional view of a semiconductor device according to a preferred embodiment of the present invention.

FIG. 13 is a cross-sectional view of a semiconductor device according to another preferred embodiment of the present invention.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

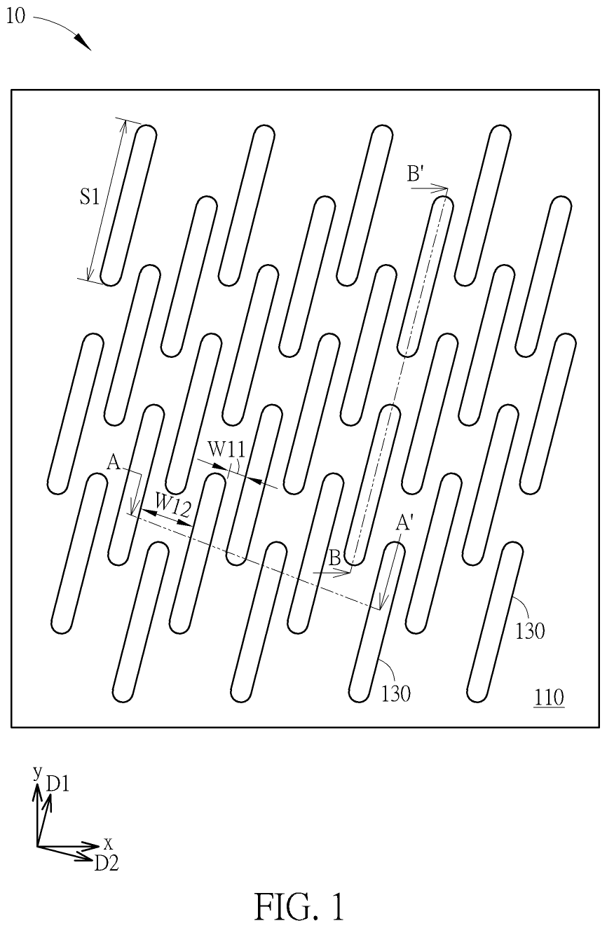

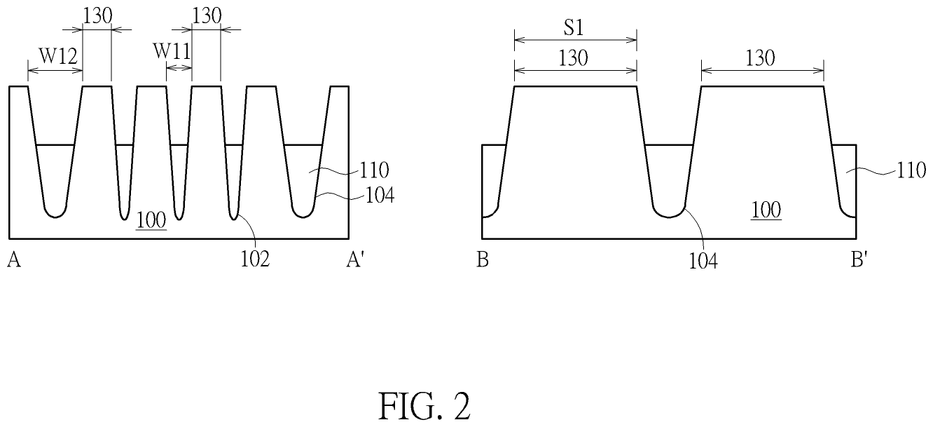

Please refer to FIG. 1 and FIG. 2, in which a semiconductor 10 according to a first embodiment of the present invention is schematically illustrated. First of all, as shown in FIG. 1 and FIG. 2, the semiconductor device 10, for example, includes a substrate 100 such as a silicon substrate, silicon-containing substrate, e.g., SiC or SiGe, or silicon-on-insulator (SOI), etc. At least one shallow trench isolation (STI) 110 is formed in the substrate 100 for defining a plurality of active areas (AAs) 130 on the substrate 100.

In an embodiment, each of the active areas 130 can be formed by way of, for example, a pattering process of the substrate 100. For example, a mask layer (not shown) is first formed on the substrate 100 while partially exposing the substrate 100, wherein the mask layer includes a plurality of patterns (not shown) adapted to define the active areas 130. An etching process is performed on the substrate 100 in the presence of the mask layer to partially remove the exposed substrate 100, thereby forming one or more trenches 102 and 104. Subsequently, a deposition process is performed to form an insulating layer (not shown), which, for example, contains an insulating material such as silicon oxide, silicon nitride or silicon oxynitride in the trenches 102 and 104. Afterwards, an etch-back process is performed to partially remove the insulating layer down to a level below the top surface of the substrate 100, thereby forming the shallow trench isolation 110. Meanwhile, the active areas 130 are defined. As a result, the active areas 130 are surrounded by the shallow trench isolation 110 and include fins protruding from the surface of the shallow trench isolation 110. Alternatively, in another embodiment, the etch-back process is performed to form a shallow trench isolation (not shown), whose top surface is substantially at the same level as the top surface of the substrate 100. The active areas 130 defined accordingly would be planar active areas (planar AAs, not shown). It is understood that the process of forming the active areas 130 is not limited to any of the above-described ones. Furthermore, a self-aligned double patterning (SADP) process or a self-aligned reverse patterning (SARP) process may be used to form the mask layer for defining the active areas 130, but it is not limited thereto.

In detail, the active areas 130, for example, are parallel to and spaced from one another and extend along a first direction D1. Each of the active areas 130 may have the same length S1. The first direction D1 is preferably not parallel to either the direction x or the direction y, as illustrated in FIG. 1. Furthermore, the active areas 130 are sequentially allocated as a plurality of columns in the first direction D1 in a manner that adjacent columns of the active areas 130 are staggered from each other in a second direction D2, which is vertical to the first direction D1. The allocation may integrally form a specific array arrangement, but it is not limited thereto. In this embodiment, adjacent active areas 130 are spaced by the shallow trench isolation 110 with a first distance W11 and a second distance W12 in the second direction D2, wherein the second distance W12 is greater than the first distance W11 because it is measured at a head-to-end connection site between two adjacent active areas 130. For example, the second distance W12 is about 2-2.5 times of, the first distance W11, but it is not limited thereto.

The semiconductor device 10 according to the first embodiment of the present invention is thus completed. The semiconductor device 10 can be subsequently formed therewith additional semiconductor active components for required functions. In an example, transistor components (not shown) can be subsequently formed on the active areas 130 of the semiconductor device 10 to serve as fin field-effect transistors (not shown). In another example, in subsequent processes, transistor components (not shown) are formed in the active areas 130 of the semiconductor device 10 and memory components (not shown) are formed on the active areas 130 to serve as elemental memory cells of a dynamic random access memory (DRAM, not shown) for receiving voltage information from bit lines (not shown) and word lines (not shown).

Those skilled in the art to which the present invention belongs could easily understand that the semiconductor device and the method of forming the same are not limited to the foregoing. Instead, they may have other embodiments or can be achieved by other means for complying with practical requirements. For example, in an alternative embodiment, insulation effects between active areas of the semiconductor device are to be improved without sacrificing the integration level, thereby ameliorating defects of the device, e.g., short-circuit, dislocation or current leakage, caused by highly integration. Other embodiments or variations of the semiconductor device and the method of forming the same will be further described below. For simplification, the following descriptions are mainly focused on the differences between embodiments, and will not repeat the similarities. In addition, the same components in different embodiments of the present invention are labeled with the same reference numerals, so as to facilitate mutual comparison among embodiments.

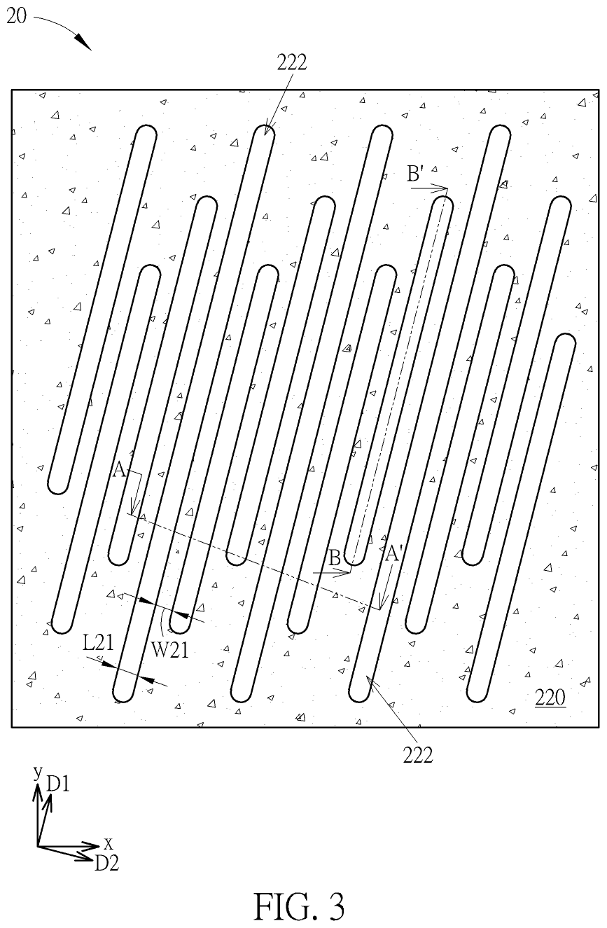

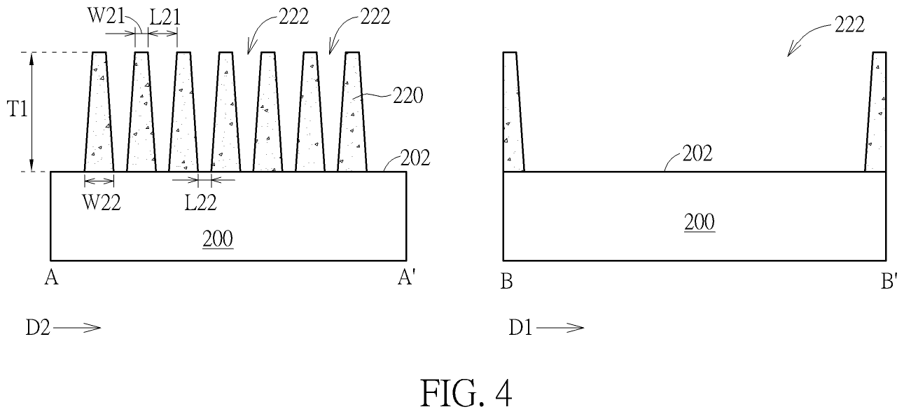

Please refer to FIG. 3 to FIG. 11, in which a semiconductor 20 according to a second embodiment of the present invention is schematically illustrated. First of all, as illustrated in FIG. 3 and FIG. 4, the semiconductor 20, for example, includes a substrate 200 such as a silicon substrate, silicon-containing substrate, e.g., SiC or SiGe, or silicon-on-insulator (SOI), etc. A mask layer 220 is formed on the substrate 200 and partially exposes the surface 202 of the substrate 200. The mask layer 220 includes a plurality of openings 222, for example, extending in a first direction D1 and parallel to and spaced from one another, wherein the first direction D1 is preferably not parallel to either the direction x or the direction y, as illustrated in FIG. 3.

In an embodiment, the mask layer 220 can be formed by way of, for example, a pattering process of the substrate 200. For example, a mask material layer (not shown) and a photoresist layer (not shown) are first formed on and overlie the substrate 200. An etching process is performed with the photoresist layer on the mask material layer to transfer the patterns of the photoresist layer onto the mask material layer so as to form the mask layer 220 with openings 222. It is to be noted that since the mask layer 220 has a certain thickness T1, e.g., about 30-40 nm, in the direction normal to the substrate 200 (not shown), each cross section of the openings 222 of the mask layer 220 in the first direction D1 or the second direction D2 would have a profile wider at top and narrower at bottom, as shown in FIG. 4. In other words, a span of the top cross section of the openings 222 in the second direction D2 is wider than that of their bottom cross section. For example, the top width L21 of one of the openings 222 illustrated in FIG. 4 is about 20-30 nm, while the bottom width 22 of one of the openings 222 illustrated in FIG. 4 is about 10-20 nm, and preferably, 0.5-0.75 times of the width L21. However, it is not limited to the above example. In contrast, the cross section of the mask layer 220 in the second direction D2 is narrower at top and wider at bottom, as shown in FIG. 4. In other words, a span of the cross section of the mask layer 220 between adjacent opening 222 in the second direction D2 is narrower than that of its bottom cross section. For example, the bottom width W22 of the mask layer 220 between adjacent opening 222 illustrated in FIG. 4 is preferably about 1.5-2 times of the top width W21 of the mask layer 220 between adjacent opening 222. However, it is not limited to the above example.

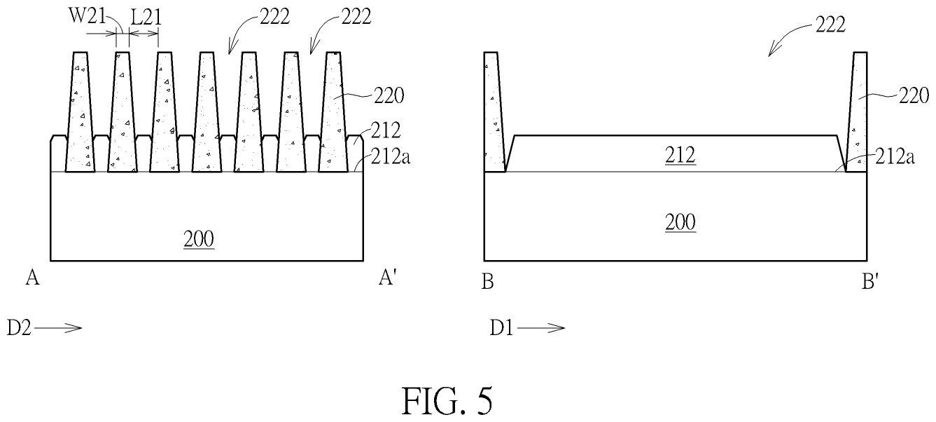

As illustrated in FIG. 5, a first deposition process is performed on the substrate 200 to form a first semiconductor sub-layer 212 in each of the openings 222 without filling up the entire opening 222. The first deposition process is preferably, but not limited to, a selective epitaxial growth (SEG) process. In detail, the first semiconductor sub-layer 212, for example, may grow along the <110> crystal plane or the <111> crystal plane, preferably along the direction with an angle of about 50-72 degrees, and more preferably 53 degrees, from the surface 202 as shown in FIG. 4. As a result, the cross section of the first semiconductor sub-layer 212 would be shaped as, but not limited to, a hexagon (also known as sigma Σ) as shown in FIG. 5, an arc (not shown) or an octagon (not shown). Alternatively, in another embodiment, the first deposition process may include a low-temperature deposition process, which causes an amorphous or polycrystalline material layer (not shown) readily formed in the opening 222, and then a heat treatment process is performed at a relatively high temperature to transform the amorphous or polycrystalline material layer into a single-crystalline material layer to form the first semiconductor sub-layer 212.

The material contained in the first semiconductor sub-layer 212 may vary with different practical requirements. For example, when the substrate 200 is a single-crystalline silicon substrate or a substrate growing along the <100> crystal face, the material for forming the first semiconductor sub-layer 212 may be selected from, but not limited to, germanium, germanium silicide (SiGe) or a material that can grow along the <110> crystal plane or <111> crystal plane. In this case, due to material similarity and lattice difference, a first interface 212a is formed between the first semiconductor sub-layer 212 and the substrate 200, as shown in FIG. 5. Furthermore, in another embodiment, the first deposition process can also be performed to form the first semiconductor sub-layer 212 in a single layer manner or a multi-layer manner. In this case, the first semiconductor sub-layer 212 may be formed with a concentration gradient of heteroatoms, e.g., germanium atoms, therein. A concentration gradient of heteroatoms, e.g., germanium atoms, in the first semiconductor sub-layer 212 may also be achieved by way of an in-situ doping process performed together with the first deposition process. In an example of having germanium atoms as heteroatoms, it is preferred to have the surface of the first semiconductor sub-layer 212 exhibit a lower concentration of germanium atoms. However, it is not limited to the above example.

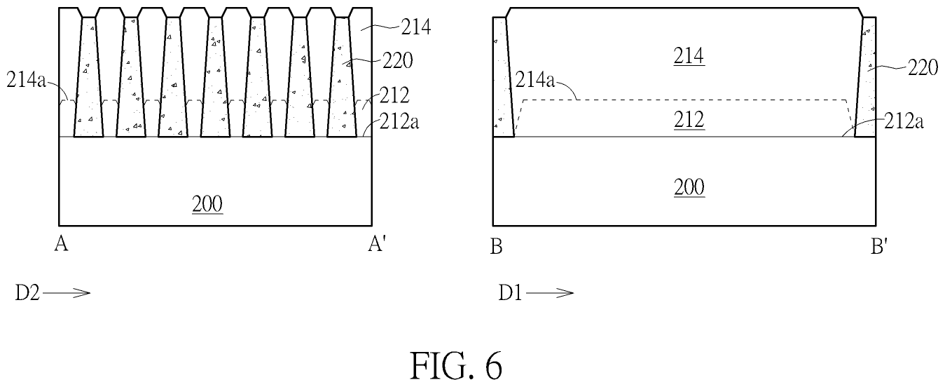

As illustrated in FIG. 6, a second deposition process is performed on the first semiconductor sub-layers 212 to form second semiconductor sub-layers 214, which fill up the vacant space in the openings 222 shown in FIG. 5. The second deposition process is preferably, but not limited to, a selective epitaxial growth (SEG) process. In detail, the second semiconductor sub-layer 214, for example, may grow along the <110> crystal plane or the <111> crystal plane, preferably along the direction with an angle of about 50-72 degrees, and more preferably 53 degrees, from the surface 202 as shown in FIG. 6. As a result, the cross section of the second semiconductor sub-layer 214 may be shaped as, but not limited to, a hexagon. Alternatively, in other embodiments, the shape of the cross section of the second semiconductor sub-layer 214 may vary with different practical requirements. For example, it may be shaped as an arc or an octagon. Furthermore, in another embodiment, the second deposition process may include a low-temperature deposition process, which causes an amorphous or polycrystalline material layer (not shown) readily formed in the openings 222, and then a heat treatment process is performed at a relatively high temperature to transform the amorphous or polycrystalline material layer into a single-crystalline material layer to form the second semiconductor sub-layer 214.

The material contained in the second semiconductor sub-layer 214 may also vary with different practical requirements. For example, the material for forming the second semiconductor sub-layer 214 may be selected from, but not limited to, germanium, germanium silicide (SiGe) or a material that can grow along the <110> crystal plane or <111> crystal plane. For example, if the first semiconductor layer 212 contains single crystalline germanium, whose lattice constant is relatively small, the second semiconductor layer 214 may contain germanium silicide, germanium boron silicide, etc., whose lattice constant is relatively large, but it is not limited thereto. In this case, due to material similarity and lattice difference, a second interface 214a is formed between the second semiconductor sub-layer 214 and the first semiconductor sub-layer 212, and the cross section of the second interface 214a has a profile like the hexagon or arc as shown in FIG. 6, but it is not limited thereto. Furthermore, the second deposition process can also be performed to form the second semiconductor sub-layer 214 in a single layer manner or a multi-layer manner. In this case, the second semiconductor sub-layer 214 may be formed with a concentration gradient of heteroatoms, e.g., germanium atoms, therein. A concentration gradient of heteroatoms, e.g., germanium atoms, in the second semiconductor sub-layer 214 may also be achieved by way of an in-situ doping process performed together with the second deposition process. In an example of having germanium atoms as heteroatoms, it is basically preferred to have the surface of the second semiconductor sub-layer 214 exhibit a lower concentration of germanium atoms or no germanium atoms, but it is not limited thereto. In another embodiment, the second semiconductor sub-layer 214 and the first semiconductor sub-layer 212 may use the same material, e.g., germanium silicide, and a concentration of the heteroatoms in the first semiconductor sub-layer 212 is greater than that in the second semiconductor sub-layer 214.

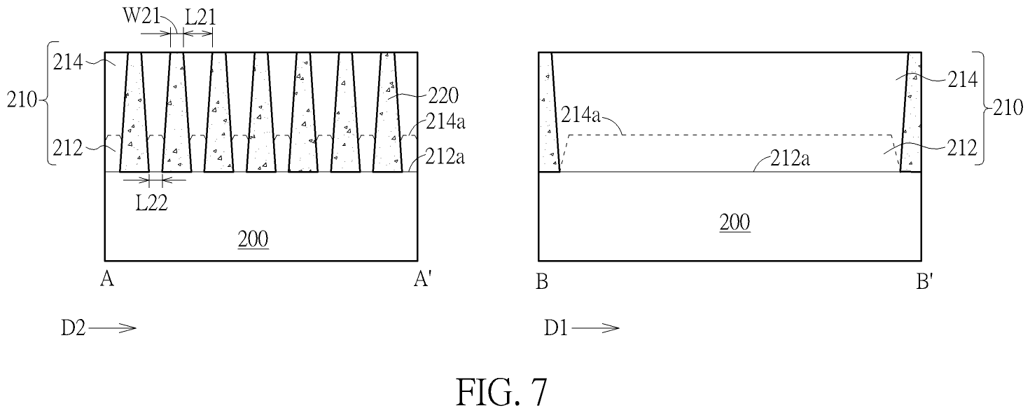

As illustrated in FIG. 7, a planarization process is performed to partially remove the second semiconductor layers 214, which protrude from the mask layer 220. As a result, the first semiconductor layers 212 and the second semiconductor layers 214 sequentially stacked on the substrate 200 commonly constitute the semiconductor layer. In this way, the semiconductor layer formed in each of the openings 222 as shown in FIG. 4 forms a plurality of active segments 210 of the semiconductor device 20. It should be noted that since each of the active segments 210 includes a semiconductor layer of a composite material, e.g., a first semiconductor sub-layer 212 and a second semiconductor sub-layer 214, whose material and lattice constant are different from those of the substrate 200, a first interface 212a would exist between the semiconductor layer and the substrate 200, and a second interface 214a would exist in the semiconductor layer between the first semiconductor sub-layer 212 and the second semiconductor sub-layer 214.

In particular, in this embodiment, the profile of each active segment 210 is defined by adjacent openings 222. Accordingly, the cross section of the active segment 210 in both the first direction D1 and the second direction D2 is wider at top and narrower bottom, as shown in FIG. 7. In an embodiment, the top of the cross section of the active segment 210 in the second direction D2 has a relatively large width L21, for example, about 20 to 30 nanometers, while the bottom of the cross section of the active segment 210 in the second direction D2 has a relatively small width L22, for example, about 10 to 20 nanometers, which is about 0.5 to 0.75 times the width L21, but it is not limited thereto.

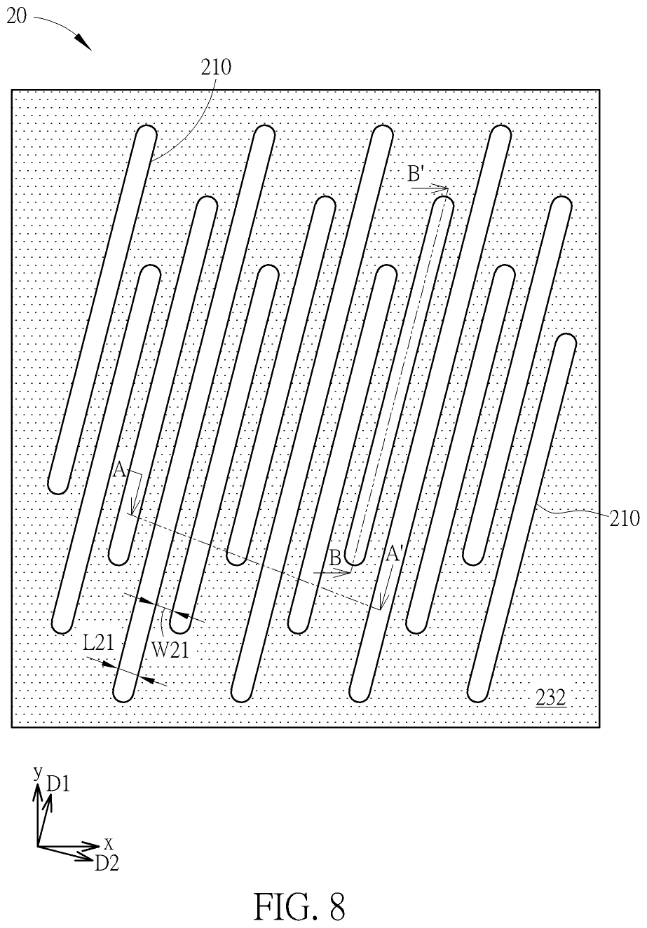

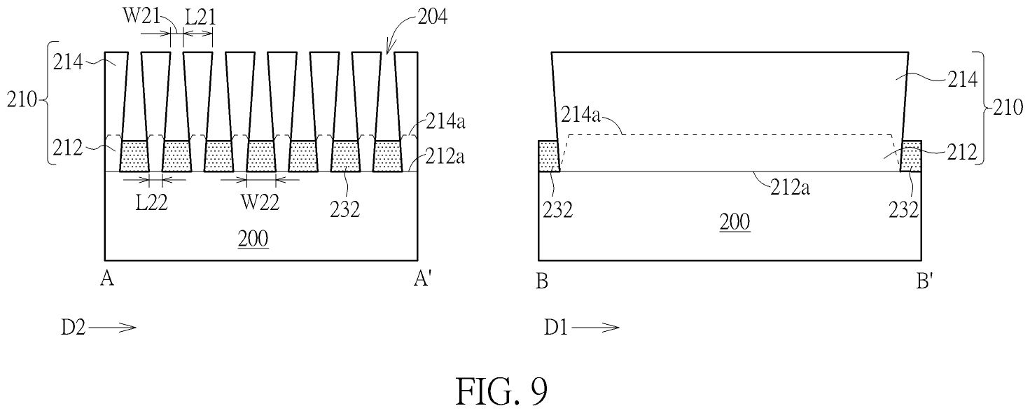

As shown in FIG. 8 to FIG. 9, the mask layer 220 is removed to form trenches 204 between the active segments 210. In this embodiment, the profile of each trench 204 is defined by the mask layer 220 as shown in FIG. 7, so that the cross section of the trench 204 in the second direction D2 presents a profile with a narrower top and a wider bottom, as shown in FIG. 9. In one embodiment, the top of the cross section of the trench 204 in the second direction D2 has a relatively small width W21, while the bottom of the cross section of the trench 204 in the second direction D2 has a relatively large width W22, which is about 1.5 to 2 times the width W21, but it is not limited thereto. Then, a deposition process and an etch-back process are sequentially performed, and an insulating layer 232 with a top surface lower than that of the active segments 210 is formed between the active segments 210. The material of the insulating layer 232 includes, but not limited to, for example silicon oxide, silicon nitride or silicon oxynitride. In an alternative embodiment, an insulating layer (not shown) is formed with a top surface substantially flush with the top surface of the active segments 210. Under this arrangement, each active segment 210 can obtain an optimized insulation effect in the second direction D2 with the facilitation of the insulating layer 232 whose cross-sectional profile is narrower at top and wider at bottom. In the meantime, each active segment 210 can maintain a certain level of integration in the second direction D2.

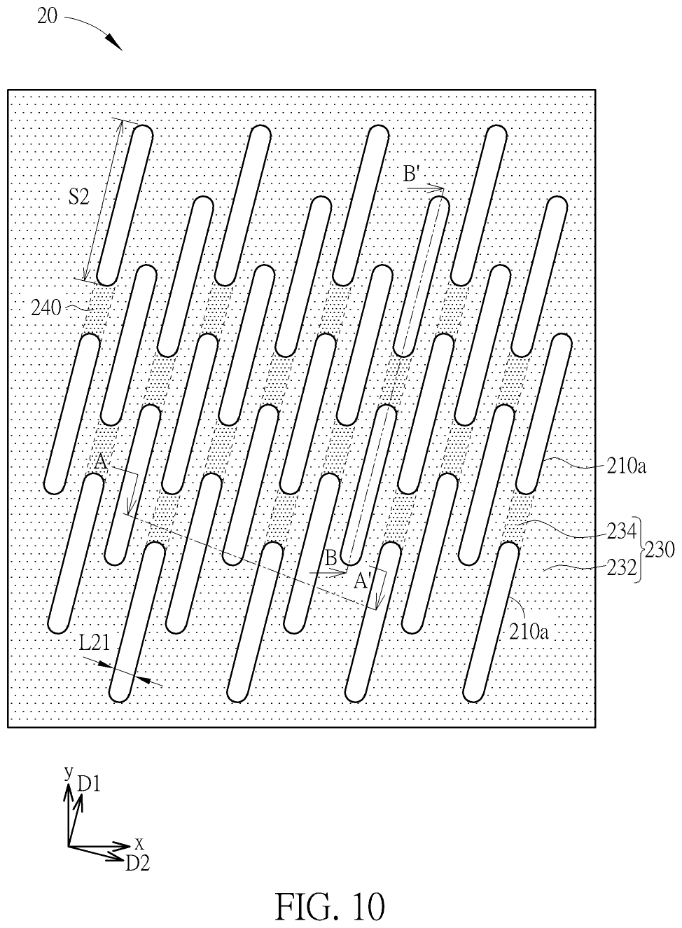

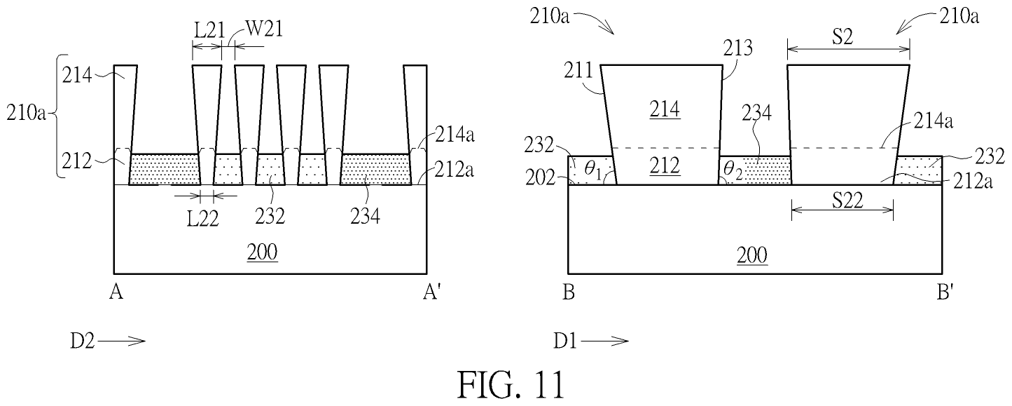

As shown in FIG. 10 and FIG. 11, a fin cut process is performed to remove unnecessary parts of the active segments 210, and a plurality of active areas 210a are formed. The active areas 210a extend in parallel along the first direction D1 at intervals and have the same length S2. A portion protruding from the surface of the insulating layer 232 in each active area 210a forms a fin. In particular, the sidewalls of the active area 210a in the first direction D1 and the second direction D2 are respectively defined by the mask layer 220 as shown in FIG. 7, or can be formed by etching in the fin cut process. The resulting sidewalls may have different slopes. In detail, the cross section of each active area 210a in the first direction D1 has two opposite sidewalls 211 and 213 with different inclinations, wherein the sidewall 211 is defined with the mask layer 220 in two deposition processes, and the included angle θ1 between the sidewall 211 and the surface 202 of the substrate 200 is influenced by the growth directions of the first semiconductor sub-layer 212 and the second semiconductor sub-layer 214, and is, for example but not limited to, about 50-72 degrees, and preferably 53 degrees. The sidewall 213 is formed by etching in the fin cut process, so it presents a relatively vertical profile, and the included angle θ2 between the sidewall 213 and the surface 202 of the substrate 200 is obviously larger than the included angle θ1, and is, for example but not limited to, about 60-80 degrees.

Afterwards, as shown in FIG. 10 to FIG. 11, another deposition process and etch-back process are sequentially performed, and an insulating layer 234 whose top surface is lower than that of the active area 210a is re-formed at the position where the active segment 210 is removed. The material of the insulating layer 234 may be the same or different from the insulating layer 232, for example but not limited to, silicon oxide, silicon nitride or silicon oxynitride. In this way, the insulating layer 232 and the insulating layer 234 can jointly the shallow form trench isolation 230 of the semiconductor device 20, surrounding each active area 210a. That is to say, the shallow trench isolation 230 of the semiconductor device 20 may also include composite materials, e.g., the insulating layer 232 and the insulating layer 234. A portion of the shallow trench isolation 230, which includes the insulating layer 232, may be formed before the fin cut process. The portion of the shallow trench isolation 230 is located between adjacent active areas 210a in the second direction D2 and surrounds most of the active areas 210a, while the other portion of the shallow trench isolation 230, which includes the insulating layer 234, is located between adjacent active areas 210a in the first direction D1. The configuration is illustrated in FIG. 10, but it is not limited thereto.

Furthermore, the method of forming the shallow trench isolation 230 is not limited to the above. In an alternative embodiment, the fin cut process can be performed directly before or after removing the mask layer 220, and then the shallow trench isolation (not shown) can be formed with a single material. Alternatively, an insulating layer (not shown) may be formed first before the fin cut process in a manner that the top surface of the insulating layer is flush with the top surface of the active segment 210. Then, after the fin cut process is performed to partially remove the active segment 210, another insulating layer (not shown) may be filled into the space where the active segment 210 is removed, so as to form the insulating layer whose top surface is flush with the top surface of the active area 210a. As a result, the top surface of the resulting shallow trench isolation (not shown) is flush with the top surface of the active area 210a, and the active area 210a is formed as a planar active area. Alternatively, the etch-back process may be performed at a later stage to etch the top surfaces of the insulating layer and the another insulating layer to a level lower than the top surface of the active area 210a, thereby forming the shallow trench isolation 230.

Thus, the fabrication of the semiconductor device 20 according to the second embodiment of the present invention is completed. According to the manufacturing method of this embodiment, the mask layer 220 as shown in FIG. 4 is used to define the profile of the active region 210a in reverse, so that each active area 210a forms a cross-sectional profile wider at top and narrower at bottom, while the shallow trench isolation 230 between the active areas 210a forms a cross-sectional profile narrower at top and wider at bottom. Under this arrangement, the active area 210a of the semiconductor device 20 can maintain a certain integration level, and at the same time, adjacent active areas 210a can be effectively isolated by the shallow trench isolation 230 whose cross-section is narrower at top and wider at bottom, thereby improving the insulation effect. Since the semiconductor device 20 formed in this embodiment has improved structural advantages, it can be used in a subsequent process to form semiconductor active components to enhance performance of the resulting device. For example, in subsequent processes, transistor components (not shown) are formed in the active areas 210a of the semiconductor device 20 to serve as fin field transistors (not shown). In another example, transistor components (not shown) and memory components (not shown) are respectively formed in the active areas 210a and on the active areas 210a of the semiconductor device 20 to serve as elemental memory cells of a dynamic random access memory (DRAM, not shown).

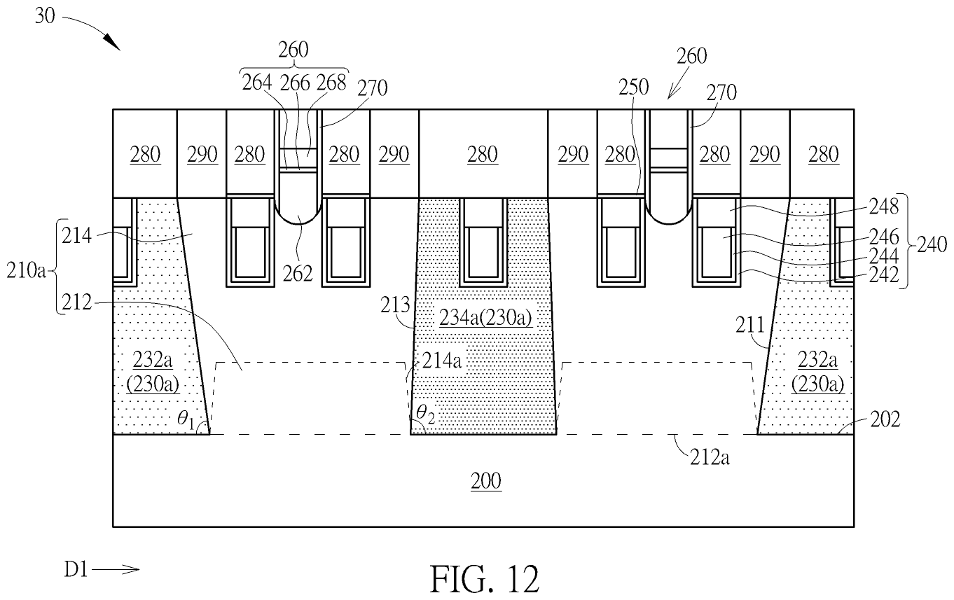

Please refer to FIG. 12, which is a schematic diagram of a semiconductor device 30 in a preferred embodiment of the present invention. The structure of the semiconductor device 30 in this embodiment is basically the same as that of the semiconductor device 20 in the aforementioned second embodiment, and also includes an active area 210a and a shallow trench isolation 230a including an insulating layer 232a and an insulating layer 234a. Moreover, the front-end process of forming the semiconductor device 30 in this embodiment is basically the same as that of forming the semiconductor device 20 in the aforementioned second embodiment illustrated with reference to FIG. 3 to FIG. 11. The similarities are not repeated here. The semiconductor device 30 in this embodiment mainly differs from the semiconductor device 20 in the aforementioned second embodiment in that the top surface of the shallow trench isolation 230a is aligned with the top surface of the active area 210a, and after forming the structure shown in FIG. 10 to FIG. 11, a plurality of buried gates 240 are formed in the active area 210a, and a plurality of gate lines 260 and a plurality of plugs 290 are alternately arranged on the active area 210a.

In detail, the substrate 200 includes, for example, a cell region (not shown), which has a relatively high component integration, and a periphery region (not shown), which has a relatively low component integration. First, a plurality of buried gates 240 are formed in the cell region and penetrate into the active area 210a. Although the overall extension direction of the active area 210a and the buried gates 240 is not specifically depicted in the drawings of this embodiment, it could be easily understood by those skilled in the art, if viewing from a top view (not shown), that the buried gates 240 extend in the X direction as exemplified in FIG. 10, while intersecting with a plurality of active areas 210a and shallow trench isolation 230a.

As shown in FIG. 12, each buried gate 240 includes a dielectric layer 242, a gate dielectric layer 244, a gate electrode 246, and a cap layer 248 stacked in sequence from bottom to top, wherein the surface of the cap layer 248 of each buried gate 240 may be flush with the surface of the active area 210a, so that each buried gate 240 can be used as a buried word line (BWL) of the semiconductor device 30. Subsequently, transistor components (not shown) may be further formed in the substrate 200. In one embodiment, the method of forming the buried gate 240 includes, but is not limited to, the following steps. For example, a plurality of trenches (not shown) are formed and penetrate into the active area 210a and the shallow trench isolation 230a. Then, the dielectric layer 242 overlying the entire surface of the trenches, the gate dielectric layer 244 overlying the surface of the lower portion of the trenches, the gate electrode 246 filling the lower portion of the trenches, and the cap layer 24 filling the upper portion of the trenches are sequentially formed, but it is not limited thereto.

It should be noted that in this embodiment, the buried gate 240 is preferably formed in the second semiconductor sub-layer 214. That is, the bottom surface of the buried gate 240 is not lower than the second interface 214a, as shown in FIG. 12. Therefore, the channel (not shown) of the buried gate 240 is also disposed in the second semiconductor sub-layer 214, for example, above the second interface 214a or overlapping the second interface 214a. In another embodiment, the bottom surface of a buried gate (not shown) may also be formed in the first semiconductor sub-layer 212 depending on practical requirements. In this case, the channel (not shown) of the buried gate may be disposed in the first semiconductor sub-layer 212 between the first interface 212a and the second interface 214a.

Please refer to FIG. 12 again. After the buried gates 240 are formed, an insulating layer 250, for example, comprising an oxide-nitride-oxide (ONO) structure, is formed on the surface of each active area 210a to completely cover the active areas 210a and the buried gates 240. Then, gate lines 260 and plugs 290 are sequentially formed on the insulating layers 250. Although the overall extension direction of the gate lines 260 is not specifically drawn in the drawings of this embodiment, it should be easily understood by those skilled in the art that from a top view (not shown) that each gate line 260 extends along the direction y as shown in FIG. 10 while intersecting with the active areas 210a and the buried gates 240. Each gate line 260 crossing the active areas 210a penetrates into each active areas 210a through the corresponding insulating layer 250 by way of a semiconductor material layer 262 formed therebelow. Accordingly, each gate line 260 can serve as a bit line of the semiconductor device 30, and the semiconductor material layer 262 serves as a bit line contact (BLC) to electrically connect the transistor components formed in the substrate 200.

In detail, each gate line 260 includes a semiconductor material layer 262 containing, for example, polysilicon, a barrier layer 264 containing, for example, titanium and/or titanium nitride, a conductive layer 266 containing, for example, a low-resistance metal such as tungsten, aluminum or copper, and a cap layer 268 containing, for example, silicon oxide, silicon nitride or silicon oxynitride, which are stacked in sequence from bottom to top. Furthermore, a spacer 270 is formed on the sidewall of the gate line 260 with a single or multiple layer structure. In an embodiment, the method of forming the gate line 260 includes, but is not limited to, the following steps. For example, an etching process is first performed with a mask layer (not shown) to partially remove the insulating layer 250 and the active area 210a under the insulating layer 250 to form a contact opening between adjacent buried gates 240. Then the mask layer is removed and a layer of semiconductor material such as polysilicon (not shown), a layer of barrier material such as titanium and/or titanium nitride (not shown), a layer of conductive material, e.g., a metal with low resistance such as tungsten, aluminum or copper, (not shown) and a layer of cover material such as silicon oxide, silicon nitride or silicon oxynitride (not shown) are sequentially formed on the active area 210a. Finally, a patterning process is performed to form the gate line 260, and meanwhile, the semiconductor material for forming the layer 262 is filled in the contact opening to form a contact.

Subsequently, after the gate lines 260 are formed, a patterning process is performed to form the plugs 290. As shown in FIG. 12, the plugs 290 are interleaving with the gate line 260 on each active area 210a and penetrate through the insulating layer 250 to directly contact opposite end portions of the active area 210a, respectively. As a result, each plug 290 overlaps the active area 210a and the shallow trench isolation 230a disposed directly thereunder in the direction normal to the substrate 200. In an embodiment, the plug 290 contains, for example, a low-resistance metal material such as aluminum (Al), titanium (Ti), copper (Cu) or tungsten (W), and serves as a storage node contact (SNC) of the semiconductor device 30 to electrically connect the transistor components formed in the substrate 200. On the other hand, an insulating structure 280 is formed on the insulating layer 250 between the plug 290 and the gate line 260 to isolate the gate line 260 from the plug 290.

In the semiconductor device 30 of this embodiment, the buried gate 240 is disposed in the active area 210a with a wider top and a narrower bottom, and the gate line 260 and the plugs 290 are disposed on the active area 210a. Under this arrangement, the active areas 210a of the semiconductor device 30 can maintain a certain level of integration, and at the same time, various components, e.g., the buried gates 240, gate lines 260 and plugs 290 etc., arranged in or above adjacent active areas 210a, can be effectively isolated with the shallow trench isolation 230a, which has a cross-sectional profile narrower at top and wider at bottom. Thus the semiconductor device 30 has significant structural advantages, which facilitate improvement on performance of the device. In addition, in a subsequent process, memory components (not shown) can be formed on the active areas 210a of the semiconductor device 30, thereby constituting elemental memory cells of a dynamic random access memory together with the transistor components in the substrate 200. In this way, the memory device manufactured with the semiconductor device 30 according to this embodiment cannot only benefit from the structural advantages of the active areas 210a to improve the integration level of the memory cells, but also ameliorate possible device defects derived from the raised level of integration. Superior performance can thus be achieved.

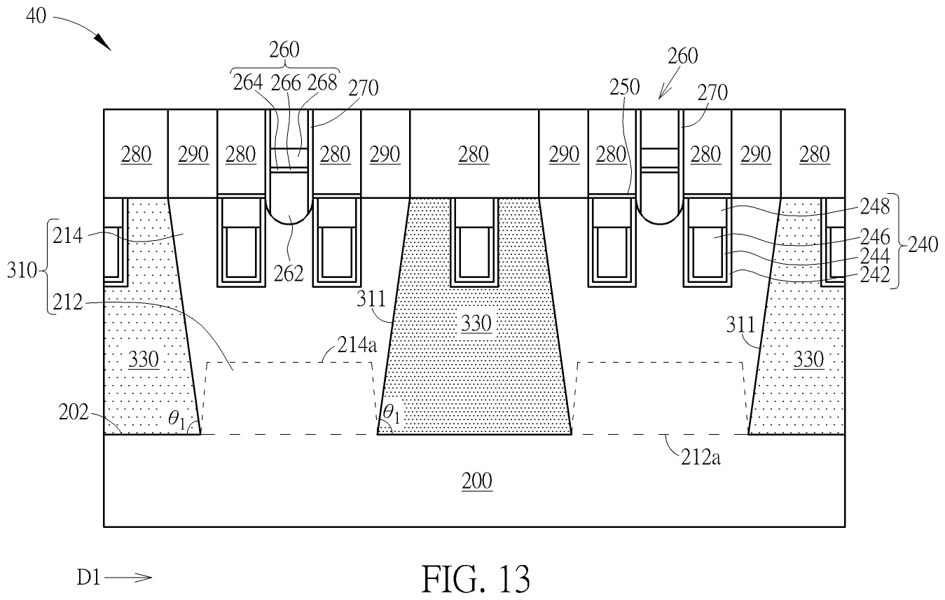

Please refer to FIG. 13, which is a schematic diagram of a semiconductor device 40 in another preferred embodiment of the present invention. The structure and manufacturing method of the semiconductor device 40 in this embodiment are basically the same as or similar to those of the semiconductor device 30 in the above-described embodiment, and the similarities are not repeated here. The semiconductor device 40 mainly differs from the semiconductor device 30 in that the cross section of each active area 310 has two opposite sidewalls 311 and 313 in the first direction D1, which have the same inclination.

In detail, in this embodiment, after forming the mask layer 220 as shown in FIG. 4, a plurality of inner blocking layers (not shown), or called cut-first blocking layers, are additionally formed in the openings 222 to cut off the openings 222, respectively, thereby defining ends of the active areas 310 in advance. Afterwards, two deposition processes are performed to form each active area 310. In this way, the implementation of the fin cut process can be omitted, and the fabrication of the shallow trench isolation 330 can be simplified at the same time. It is only necessary to form the shallow trench isolation 330 of a single material directly after forming the active area 310 to have the top surface of the shallow trench isolation 330 flush with the top surface of the active region 310. In addition, in this embodiment, the sidewalls of the active area 310 in the first direction D1 or the second direction D2 are both defined with the mask layer 220 as shown in FIG. 4, so they can have the same slope. For example, the two opposite side walls 311 and 313 of the cross section of each active area 310 in the first direction D1 have the same included angle θ1 with the surface 202 of the substrate 200, as shown in FIG. 13.

Likewise, on the condition that the active areas 310 of the semiconductor device 40 maintain a certain level of integration under this arrangement, various components, e.g., the buried gates 240, gate lines 260 and plugs 290, etc., arranged in or above adjacent active areas 210a, can be effectively isolated with the shallow trench isolation 330, which has a cross-sectional profile narrower at top and wider at bottom. Thus the semiconductor device 40 has significant structural advantages, which facilitate improvement on performance of the device. In addition, in a subsequent process, memory components (not shown) can be formed on the active areas 310 of the semiconductor device 40, thereby constituting elemental memory cells of a dynamic random access memory together with the transistor components in the substrate 200. In this way, the memory device manufactured with the semiconductor device 40 according to this embodiment cannot only benefit from the structural advantages of the active areas 310 to improve the integration level of the memory cells, but also ameliorate possible device defects derived from the raised level of integration.

On the whole, the method of forming a semiconductor device according to the present invention uses a mask layer to define the profile of active areas in reverse, so that each of the active areas has a cross-sectional profile with a wider top and a narrower bottom, while the shallow trench isolation between adjacent active regions has a cross-sectional profile with a narrower top and a wider bottom. On the condition that the semiconductor device formed by the manufacturing process according to the present invention maintains a certain level of integration under this arrangement, effective isolation between adjacent active areas can be provided with the shallow trench isolation having a cross-sectional profile narrower at top and wider at bottom, thereby improving the insulation effect. In this way, the semiconductor device can have significant structural advantages so as to be subsequently formed therewith additional semiconductor active components. The possible device defects derived from the raised level of integration can also be ameliorated.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate having a surface;
a plurality of active areas disposed on the surface of the substrate, wherein each of the plurality of active areas comprises a semiconductor layer, and the semiconductor layer and the substrate have a first interface therebetween;
a shallow trench isolation disposed on the substrate and surrounding the plurality of active areas; and
a plurality of buried gates, each being buried in one of the plurality of active areas and disposed above the first interface.

2. The semiconductor device according to claim 1, wherein the semiconductor layer contains heteroatoms distributed in a concentration gradient manner.

3. The semiconductor device according to claim 2, wherein the semiconductor layer comprises a first semiconductor sub-layer and a second semiconductor sub-layer, which are stacked in sequence and have a second interface therebetween, and the second interface has an arc shaped cross section or a hexagon shaped cross section.

4. The semiconductor device according to claim 3, wherein a lattice constant of the first semiconductor sub-layer is smaller than that of the second semiconductor sub-layer, and a concentration of the heteroatoms in the first semiconductor sub-layer is greater than a concentration of the heteroatoms in the second semiconductor sub-layer.

5. The semiconductor device according to claim 3, wherein a channel of one of the plurality of buried gates overlaps the second interface.

6. The semiconductor device according to claim 3, wherein a channel of one of the plurality of buried gates is disposed above the second interface.

7. The semiconductor device according to claim 3, wherein a channel of one of the plurality of buried gates is disposed between the first interface and the second interface.

8. The semiconductor device according to claim 1, further comprising:
at least one gate line disposed on the substrate between adjacent two of the plurality of buried gates; and
a plurality of plugs disposed on the plurality of active areas and alternately arranged with the at least one gate line, wherein each of the plurality of plugs sequentially overlaps a corresponding one of the plurality of active areas and the shallow trench isolation in a direction normal to the substrate.

9. The semiconductor device according to claim 1, wherein a cross section of each of the plurality of active areas is wider at top and narrower at bottom.

10. The semiconductor device according to claim 9, wherein the cross-section of each of the plurality of active areas comprises sidewalls of different slopes.

11. A method of forming a semiconductor device, comprising:
providing a substrate having a surface;
forming a plurality of active areas on the surface of the substrate, wherein each of the plurality of active areas comprises a semiconductor layer, and the semiconductor layer and the substrate have a first interface therebetween;
forming a shallow trench isolation on the substrate, the shallow trench isolation surrounding the plurality of active areas; and
forming a plurality of buried gates, each of which is buried in one of the plurality of active areas and disposed above the first interface.

12. The method according to claim 11, wherein forming the plurality of active areas comprises:
forming a mask layer on the surface, the mask layer comprising a plurality of openings;
forming the semiconductor layer in each of the plurality of openings through the mask layer; and
removing the mask layer.

13. The method according to claim 12, wherein during forming the semiconductor layer, an in-situ doping process is performed to provide heteroatoms in the semiconductor layer in a concentration gradient manner.

14. The method according to claim 12, wherein forming the semiconductor layer comprises:
depositing a material layer in each of the plurality of openings; and
transforming the material layer into the semiconductor layer by performing a heat treatment process.

15. The method according to claim 12, wherein forming the semiconductor layer comprises:
depositing a first semiconductor sub-layer in each of the plurality of openings by performing a first deposition process; and
depositing a second semiconductor sub-layer on the first semiconductor sub-layer in each of the plurality of openings by performing a second deposition process so that the first semiconductor sub-layer and the second semiconductor sub-layer have a second interface therebetween.

16. The method according to claim 12, wherein forming the plurality of active areas further comprises:
performing a cutting process after removing the mask layer to divide the semiconductor layer into the plurality of active areas.

17. The method according to claim 16, wherein the cutting process is performed before forming the shallow trench isolation.

18. The method according to claim 16, wherein the cutting process is performed after forming the shallow trench isolation.

19. The method according to claim 12, wherein forming the plurality of active areas further comprises:
forming a plurality of inner blocking layers to cut off the plurality of openings, respectively; and
forming the plurality of active areas through the mask layer and the inner blocking layers.

20. The method according to claim 11, further comprising:
forming at least one gate line on the surface, the at least one gate line being disposed between adjacent two of the buried gates; and
forming a plurality of plugs on the substrate, the plurality of plugs being disposed on the plurality of active areas and alternately arranged with the at least one gate line, wherein each of the plurality of plugs sequentially overlaps a corresponding one of the plurality of active areas and the shallow trench isolation in a direction normal to the substrate.
